(19) United States
(12) Patent Application Publication
(10) Pub. No.: US 2013/0161836 A1
(43) Pub. Date: Jun. 27, 2013

(54) SEMICONDUCTOR PACKAGE HAVING INTERPOSER COMPRISING A PLURALITY OF SEGMENTS

(71) Applicants: Kun-Dae YEOM, Cheonan-si (KR); Young-Min KIM, Asan-si (KR); Jong-Bo SHIM, Asan-si (KR); Woo-Dong LEE, Cheonan-si (KR)

(72) Inventors: Kun-Dae YEOM, Cheonan-si (KR); Young-Min KIM, Asan-si (KR); Jong-Bo SHIM, Asan-si (KR); Woo-Dong LEE, Cheonan-si (KR)

(73) Assignee: SAMSUNG ELECTRONICS CO., LTD., Suwon-si (KR)

(21) Appl. No.: 13/584,637

(22) Filed: Aug. 13, 2012

(30) Foreign Application Priority Data
Dec. 27, 2011 (KR) 10-2011-0143554

(51) Int. Cl. H01L 23/48

(52) U.S. Cl. 257/778; 257/E23.01

(57) ABSTRACT

Provided is a semiconductor package comprising a substrate, a semiconductor chip formed on the substrate, and an interposer including a plurality of segments which are separated from each other and arranged on the substrate to surround the semiconductor chip. And a stacked package for multiple chips including the semiconductor package with a plurality of segments of an interposer is provided.

### CROSS-REFERENCE TO RELATED APPLICATION

This application claims priority from Korean Patent Application No. 10-2011-0143554 filed on Dec. 27, 2011 in the Korean Intellectual Property Office, and all the benefits accruing therefrom under 35 U.S.C. 119, the contents of which are herein incorporated by reference in its entirety.

### BACKGROUND

1. Technical Field

The present inventive concept relates to a semiconductor package having an interposer comprising a plurality of segments.

2. Description of the Related Art

A package-on-package type semiconductor package may be manufactured by mounting a top package on a bottom package. Further, an interposer may be used to connect a printed circuit board (PCB) of the bottom package with a printed circuit board of the top package.

The interposer may be included in the bottom package. For example, the interposer may be formed with a cavity or slot therein. Unfortunately, however, the shape of the interposer may be deformed, such as during a drilling process in which the cavity is formed in the interposer. Accordingly, when the interposer is mounted on the printed circuit board of the bottom package, a contact failure may occur due to the deformation of the interposer.

### SUMMARY

The present inventive concept provides a semiconductor package having an interposer including a plurality of segments, capable of reducing deformation of the interposer and achieving stable contact between the interposer and a printed circuit board of a bottom package. Of course, the objects of the present inventive concepts are not limited thereto, and additional objects of the present inventive concepts will be described in or be apparent from the following description.

According to an aspect of the present inventive concepts, a semiconductor package comprises a substrate, a semiconductor chip formed on the substrate, and an interposer including a plurality of segments which are separated from each other and arranged on the substrate to surround the semiconductor chip.

According to another aspect of the present inventive concepts, a semiconductor package comprises a substrate, a semiconductor chip formed on the substrate and including first and second side surfaces adjacent to each other, an interposer including a first segment adjacent to the first side surface of the semiconductor chip and a second segment adjacent to the second side surface of the semiconductor chip. The first and second segments may be formed separately from each other on the substrate, and a sealant can be formed to fill up a space between the first and second segments.

### BRIEF DESCRIPTION OF THE DRAWINGS

The above and other aspects and features of the present inventive concepts will become more apparent by describing in detail exemplary embodiments thereof with reference to the attached drawings, in which:

FIG. 1 is a somewhat schematic cross-sectional view showing a package-on-package type semiconductor package including a first semiconductor package in accordance with a first embodiment of the present inventive concepts;

FIG. 2 is a somewhat schematic perspective view showing the first semiconductor package in accordance with the first embodiment of the present inventive concepts;

FIG. 3 is a somewhat schematic plan view of the first semiconductor package of FIG. 2;

FIG. 4 is a somewhat schematic cross-sectional view of the first semiconductor package taken along line A-A′ of FIG. 2;

FIG. 5 is a somewhat schematic cross-sectional view of the first semiconductor package taken along line B-B′ of FIG. 2;

FIG. 6 is a somewhat schematic perspective view for explaining a method of manufacturing the first semiconductor package of FIG. 2;

FIG. 7 is a somewhat schematic plan view of a first semiconductor package in accordance with a second embodiment of the present inventive concepts;

FIG. 8 is a somewhat schematic plan view of a first semiconductor package in accordance with a third embodiment of the present inventive concepts; and

FIG. 9 is a somewhat schematic plan view of a first semiconductor package in accordance with a fourth embodiment of the present inventive concepts.

### DETAILED DESCRIPTION OF THE EMBODIMENTS

Advantages and features of the present inventive concepts and methods of accomplishing the same may be understood more readily by reference to the following detailed description of preferred embodiments and the accompanying drawings. The present inventive concepts may, however, be embodied in many different forms and should not be construed as being limited to the specific embodiments set forth herein. Rather, these embodiments are provided so that this disclosure will be thorough and complete and will fully convey the scope of the inventive concepts to those skilled in the art, with the limits of the present inventive concepts defined only by the appended claims. In the drawings, the thickness of layers and regions may be exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concepts.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

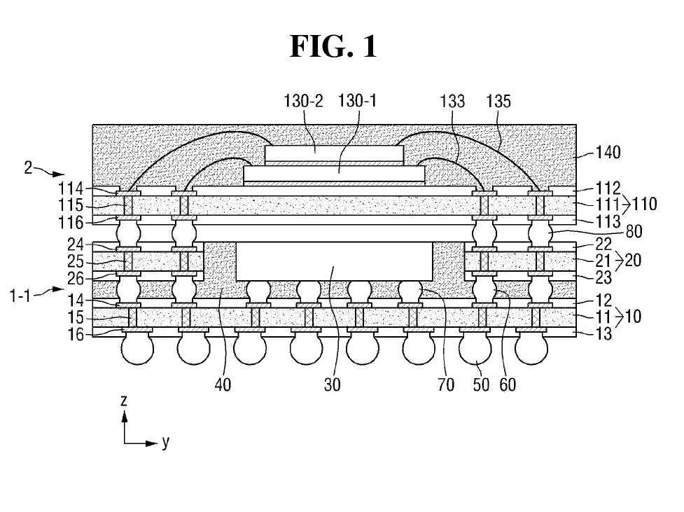

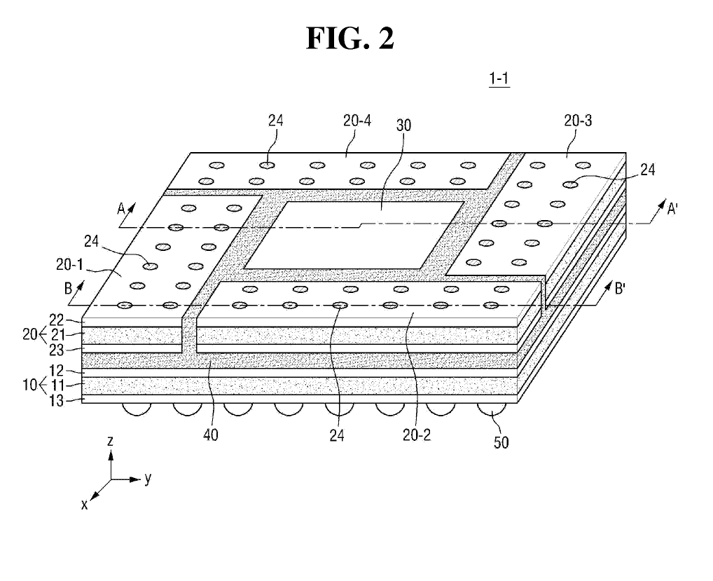

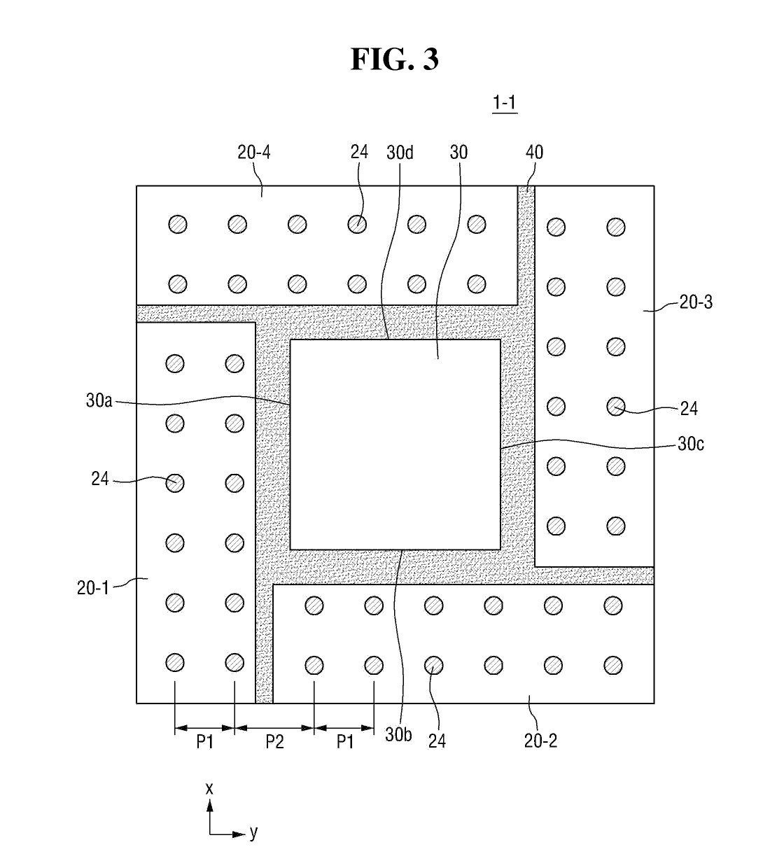

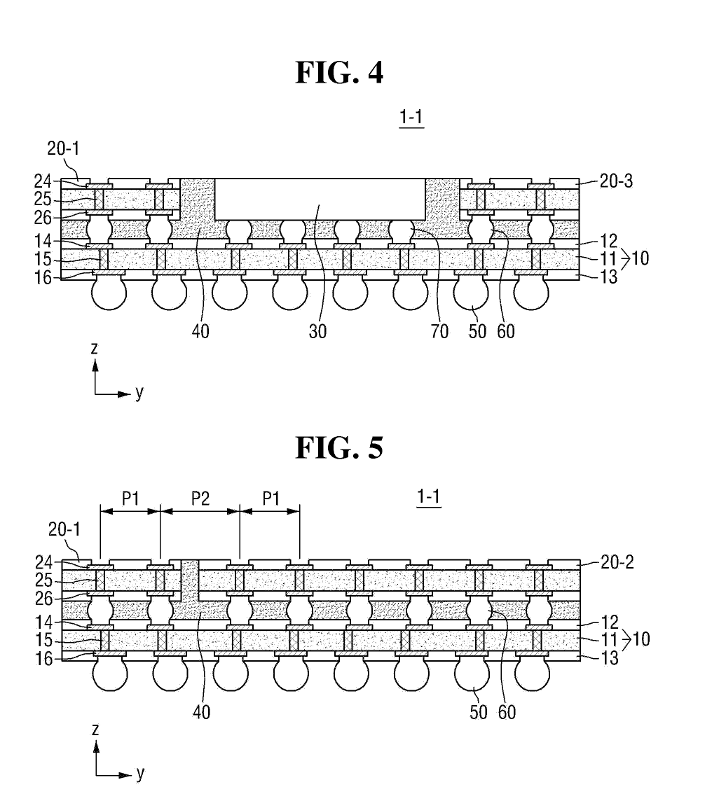

A first semiconductor package in accordance with a first embodiment of the present inventive concepts will now be described with reference to FIGS. 1 through 5. FIG. 1 is a somewhat schematic cross-sectional view showing a package-on-package type semiconductor package including a first semiconductor package in accordance with the first embodiment. FIG. 2 is a somewhat schematic perspective view illustrating the first semiconductor package of the package-on-package type semiconductor package of FIG. 1. FIG. 3 is a somewhat schematic plan view of the first semiconductor package of FIG. 2. FIG. 4 is a somewhat schematic cross-sectional view of the first semiconductor package taken along line A-A′ of FIG. 2. FIG. 5 is a somewhat schematic cross-sectional view of the first semiconductor package taken along line B-B′ of FIG. 2.

Referring to FIG. 1, the semiconductor package shown is a package-on-package (PoP) type semiconductor package in which a second semiconductor package 2 is mounted on a first semiconductor package 1-1. The first semiconductor package 1-1 may be a bottom package including an interposer, and the second semiconductor package 2 may be a top package. Further, the first semiconductor package 1-1 and the second semiconductor package 2 may be electrically connected to each other by fourth external connection terminals 80.

More specifically, the first semiconductor package 1-1 may include a first substrate 10, an interposer 20, a first semiconductor chip 30 and a first sealant 40.

The first substrate 10 may include a first core material layer 11, first through electrodes 15 passing through the first core material layer 11, first and second pads 14 and 16 connected to both ends of the first through electrodes 15, and first and second protection layers 12 and 13 covering both upper and lower surfaces of the first core material layer 11 while exposing the first and second pads 14 and 16.

First external connection terminals 50 may be formed on the second pads 16 of the first substrate 10. The package-on-package type semiconductor package may receive electrical signals from the outside, or transmit electrical signals to the outside through the first external connection terminals 50. The first external connection terminals 50 and second to fifth external connection terminals 60, 70, 71 and 80 may, for example, be conductive balls or solder balls, but they are not limited thereto.

The interposer 20 may be disposed on the first substrate 10. The interposer 20 may be located on the side surface of the first semiconductor chip 30, but a more detailed explanation of the relative arrangement between the interposer 20 and the first semiconductor chip 30 will be described later. The interposer 20 may electrically connect the first substrate 10 to the second semiconductor package 2. Specifically, the interposer 20 may be electrically connected to the first substrate 10 through the second external connection terminals 60, and may be electrically connected to the second semiconductor package 2 through the fourth external connection terminals 80.

The interposer 20 may include a second core material layer 21, second through electrodes 25 passing through the second core material layer 21, third and fourth pads 24 and 26 connected to both ends of the second through electrodes 25, and third and fourth protection layers 22 and 23 covering opposing surfaces of the second core material layer 21 while exposing the third and fourth pads 24 and 26. The fourth external connection terminals 80 may be formed on the third pads 24, and the second external connection terminals 60 may be formed on the fourth pads 26.

The first semiconductor chip 30 may be disposed on the first substrate 10. The first semiconductor chip 30 may be manufactured by using silicon, silicon-on-insulator (SOI), silicon germanium or the like, but it is not limited thereto. Further, a multilayer wiring, a plurality of transistors, a plurality of passive elements and the like may, for example, be integrated in the first semiconductor chip 30. The first semiconductor chip 30 may be electrically connected to the first substrate 10 through the third external connection terminals 70.

Although in this embodiment the first semiconductor chip 30 is flip-chip bonded to the first substrate 10 through the third external connection terminals 70, other embodiments are contemplated, for example, in which the first semiconductor chip 30 may be wire bonded to the first substrate 10.

The first sealant 40 may be formed to fill up a space between the interposer 20 and the first substrate 10, a space between the interposer 20 and the first semiconductor chip 30, and a space between the first semiconductor chip 30 and the first substrate 10. The first sealant 40 may, for example, be an epoxy molding compound (EMC) or underfill material. The sealant is not limited thereto, however, and various types of encapsulants may be used as the first sealant 40.

Further, the second semiconductor package 2 may include a second substrate 110, second and third semiconductor chips 130-1 and 130-2, and a second sealant 140.

The second substrate 110 may include a third core material layer 111, third through electrodes 115 passing through the third core material layer 111, fifth and sixth pads 114 and 116 connected to both ends of the third through electrodes 115, and fifth and sixth protection layers 112 and 113 covering opposing surfaces of the third core material layer 111 while exposing the fifth and sixth pads 114 and 116.

The fourth external connection terminals 80 may be formed on the sixth pads 116 of the second substrate 110. The second semiconductor package 2 may be electrically connected to the first semiconductor package 1-1 through the fourth external connection terminals 80.

Second and third semiconductor chips 130-1 and 130-2 may be formed on the second substrate 110. The second and third semiconductor chips 130-1 and 130-2 may be wire bonded to the second substrate 110 through first and second wires 133 and 135 respectively, but the inventive concepts are not limited thereto. For example, the first and second wires 133 and 135 may be electrically connected to the fifth pads 114 of the second substrate 110.

In FIG. 1, the first semiconductor chip 30 may be a controller, for example, and the second and third semiconductor chips 130-1 and 130-2 may be volatile or non-volatile memory chips such as DRAM, SRAM, NAND flash memory, MRAM, and RRAM, etc. Where bonding pads of a memory chip are arranged in only one side of the memory chip, the bonding wire 133 or 135 may be formed on only one side of the memory chip. Thus, when multiple chips such as the above memory chips are stacked, directions of the first and second wires 133 and 135 may vary according to the position of the bonding pads of the first and second memory chips. It should be noted, however, that the type of the stacked semiconductor chips is not limited to memories. For example, they can be controllers or combinations of memories and controllers.

A structure of the interposer 20 included in the first semiconductor package 1-1 will now be described with reference to FIGS. 2 to 5, in accordance with an embodiment of the present inventive concepts.

Referring to FIGS. 2 and 3, the first semiconductor chip 30 may be formed on the first substrate 10. Further, the interposer 20 may be arranged on the first substrate 10 to surround the first semiconductor chip 30. However, the interposer 20 is not a single unit, and may include a plurality of segments 20-1, 20-2, 20-3 and 20-4 that are separated from each other. Although the interposer 20 of this embodiment includes first to fourth segments 20-1, 20-2, 20-3 and 20-4 in FIGS. 2 and 3, the number of segments included in the interposer 20 is not limited thereto and may vary.

The segments 20-1, 20-2, 20-3 and 20-4 may be arranged in a rectangular shape to surround the first semiconductor chip 30, but the inventive concepts are not limited thereto. The segments 20-1, 20-2, 20-3 and 20-4 may be arranged separately from the first semiconductor chip 30 while surrounding the first semiconductor chip 30. The first sealant 40 may be formed to fill up a space between neighboring segments 20-1, 20-2, 20-3 and 20-4. Also, the first sealant 40 may fill up a space between the first semiconductor chip 30 and each of the segments 20-1, 20-2, 20-3 and 20-4.

The segments 20-1, 20-2, 20-3 and 20-4 may be arranged on the first substrate 10. Accordingly, each of the segments 20-1, 20-2, 20-3 and 20-4 may be separated from the first substrate 10 by the same distance. Since the segments 20-1, 20-2, 20-3 and 20-4 may be arranged in a rectangular shape, a cavity may be formed on the inside of the segments 20-1, 20-2, 20-3 and 20-4 arranged in a rectangular shape. Further, the first semiconductor chip 30 may be located in the cavity.

For example, the first semiconductor chip 30 may include first to fourth side surfaces 30a, 30b, 30c and 30d. The first and second side surfaces 30a and 30b and the third and fourth side surfaces 30c and 30d may be adjacent to each other, respectively. The first segment 20-1 may be adjacent to the first surface 30a of the first semiconductor chip 30, and the second segment 20-2 may be adjacent to the second surface 30b of the first semiconductor chip 30. The third segment 20-3 may be adjacent to the third surface 30c, and the fourth segment 20-4 may be adjacent to the fourth surface 30d of the first semiconductor chip 30.

The first to fourth segments 20-1, 20-2, 20-3 and 20-4 may be arranged in a rectangular shape with a cavity formed at its center. The first semiconductor chip 30 may be located in the cavity.

The shape of the segments 20-1, 20-2, 20-3 and 20-4 may, for example, form a rectangular shape, but is the inventive concepts are not limited thereto. Further, the segments 20-1, 20-2, 20-3 and 20-4 may have the same length, but is the inventive concepts are not limited thereto. An embodiment in which the segments 20-1, 20-2, 20-3 and 20-4 have different lengths will be described later.

In the first semiconductor package 1-1 in accordance with the first embodiment of the present inventive concepts, the interposer 20 consists of the segments 20-1, 20-2, 20-3 and 20-4 instead of a single unit. Accordingly, it is possible to reduce thermal stress applied to the interposer 20.

When the first semiconductor package 1-1 is used while being mounted on a semiconductor device, heat is generated and expansion or contraction occurs due to the generated heat, thereby causing thermal stress. However, if the interposer 20 consists of the segments 20-1, 20-2, 20-3 and 20-4, the length of one unit can be shortened compared to a case where the interposer 20 is formed of a single unit. Accordingly, even though heat is generated, the expansion or contraction of each unit is reduced, thereby reducing thermal stress. Therefore, it is possible to ensure better reliability of the first semiconductor package 1-1 in accordance with the first embodiment of the present inventive concepts.

Referring to FIG. 4, the first semiconductor chip 30 may be located between the first segment 20-1 and the third segment 20-3. For example, an upper surface of the first semiconductor chip 30 may be flush with upper surfaces of the first and third segments 20-1 and 20-3. That is, a distance from the first substrate 10 to the upper surface of the first semiconductor chip 30 may be equal to a distance from the first substrate 10 to the upper surface of the interposer 20. However, without being limited thereto, the upper surface of the first semiconductor chip 30 may be located at a lower level than that of the upper surface of the interposer 20.

Referring to FIGS. 3 and 5, the first segment 20-1 and the second segment 20-2 may be located on the first substrate 10. Since FIG. 5 is a cross-sectional view showing the first segment 20-1 in its thickness direction and the second segment 20-2 in its length direction, the length of the first segment 20-1 is shorter than the length of the second segment 20-2.

Further, a pitch P1 of the third pads 24 of the first to fourth segments 20-1, 20-2, 20-3 and 20-4 may be equal. Similarly, a pitch P1 of the fourth pads 26 of the first to fourth segments 20-1, 20-2, 20-3 and 20-4 may be equal. However, a pitch between the pads belonging to different segments may be different from a pitch between the pads belonging to the same segment. Also, the pitch P1 of the fourth pads 26 in a segment may vary according to their positions relative to the sixth pads 116 of the second package 2 in FIG. 1.

For example, referring to FIG. 5, a pitch P2 between the rightmost third pad 24 among the third pads 24 of the first segment 20-1 and the leftmost third pad 24 among the third pads 24 of the second segment 20-2 may be different from the pitch P1 of the third pads 24 of the first to fourth segments 20-1, 20-2, 20-3 and 20-4. Such difference in pitch may occur because the first sealant 40 is formed to fill up a space between the rightmost third pad 24 among the third pads 24 of the first segment 20-1 and the leftmost third pad 24 among the third pads 24 of the second segment 20-2. Such difference in pitch may be applied to the other adjacent segments.

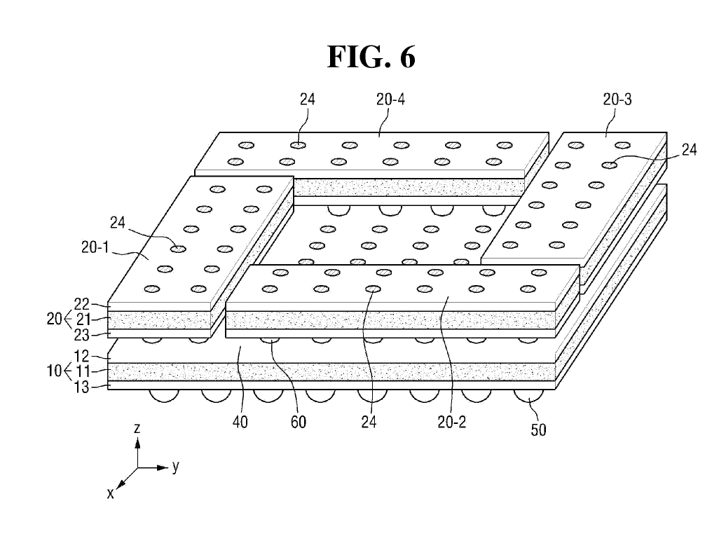

A method of manufacturing the first semiconductor package in accordance with the first embodiment of the present inventive concepts will now be described with reference to FIGS. 1 to 6, wherein FIG. 6 is a somewhat schematic perspective view for explaining a method of manufacturing the first semiconductor package of FIG. 2.

First, referring to FIGS. 1 and 6, the first to fourth segments 20-1, 20-2, 20-3 and 20-4 constituting the interposer 20 may be manufactured. For example, one plate may be formed which includes the second core material layer 21, with the second through electrodes 25 passing through the second core material layer 21. The third and fourth pads 24 and 26 can be connected to both ends of the second through electrodes 25, and the third and fourth protection layers 22 and 23 can be formed to cover opposing surfaces of the second core material layer 21 while exposing the third and fourth pads 24 and 26.

For example, since the first to fourth segments 20-1, 20-2, 20-3 and 20-4 may be formed having a stick-like shape, they may be formed by sawing or blading the above-described plate. In a manufacturing process of the first to fourth segments 20-1, 20-2, 20-3 and 20-4, sawing or blading can be used instead of drilling. Accordingly, it is possible to reduce the stress applied to the first to fourth segments 20-1, 20-2, 20-3 and 20-4 during the manufacturing process. Consequently, it is further possible to reduce deformation such as warpage, in which the first to fourth segments 20-1, 20-2, 20-3 and 20-4 are bent or twisted.

Further, since sawing or blading is more easily performed compared to drilling, excellent manufacturability can be achieved through this method of manufacturing the first semiconductor package in accordance with the first embodiment of the present inventive concepts.

Further, since the segments 20-1, 20-2, 20-3 and 20-4 having a stick-like shape are formed by sawing or blading the above-described plate, it is possible to reduce the amount of the plate wasted by being rendered unusable through the manufacturing process. It is therefore possible to improve yield of the segments and reduce the manufacturing cost of the first semiconductor package 1-1.

Subsequently, referring to FIG. 6, the first to fourth segments 20-1, 20-2, 20-3 and 20-4 may be mounted on the first substrate 10 by using the second external connection terminals 60. Specifically, the first to fourth segments 20-1, 20-2, 20-3 and 20-4 may be arranged in a rectangular shape. Consequently, a cavity surrounded by the first to fourth segments 20-1, 20-2, 20-3 and 20-4 may be formed.

Since bending or twisting of the first to fourth segments 20-1, 20-2, 20-3 and 20-4 is reduced, this manufacturing process can help maintain a constant distance from the first substrate 10, thereby preventing a contact failure from occurring when the segments 20-1, 20-2, 20-3 and 20-4 are mounted on the first substrate 10.

Referring now to FIG. 2, the first semiconductor chip 30 may be mounted on the first substrate 10 in the cavity formed by the first to fourth segments 20-1, 20-2, 20-3 and 20-4 using the third external connection terminals 70 (see FIG. 1). For example, the first semiconductor chip 30 may be flip-chip bonded to the first substrate 10, but is the inventive concepts are not limited thereto.

Then, the first sealant 40 may be formed to fill up a space between the first substrate 10 and the first to fourth segments 20-1, 20-2, 20-3 and 20-4, a space between the first semiconductor chip 30 and the first to fourth segments 20-1, 20-2, 20-3 and 20-4, and a space between the first semiconductor chip 30 and the first substrate 10. In this method, since the interposer 20 includes a plurality the segments 20-1, 20-2, 20-3 and 20-4 which are separated from each other, rather than constructed from a single unit, it is possible to ensure mobility of the first sealant 40 compared to a case where the interposer 20 is formed of a single unit. Thus, it is possible to prevent a void from being formed in the first semiconductor package 1-1.

Subsequently, the first external connection terminals 50 (for example, such as solder balls) may be formed on the second pads 16 of the first substrate 10.

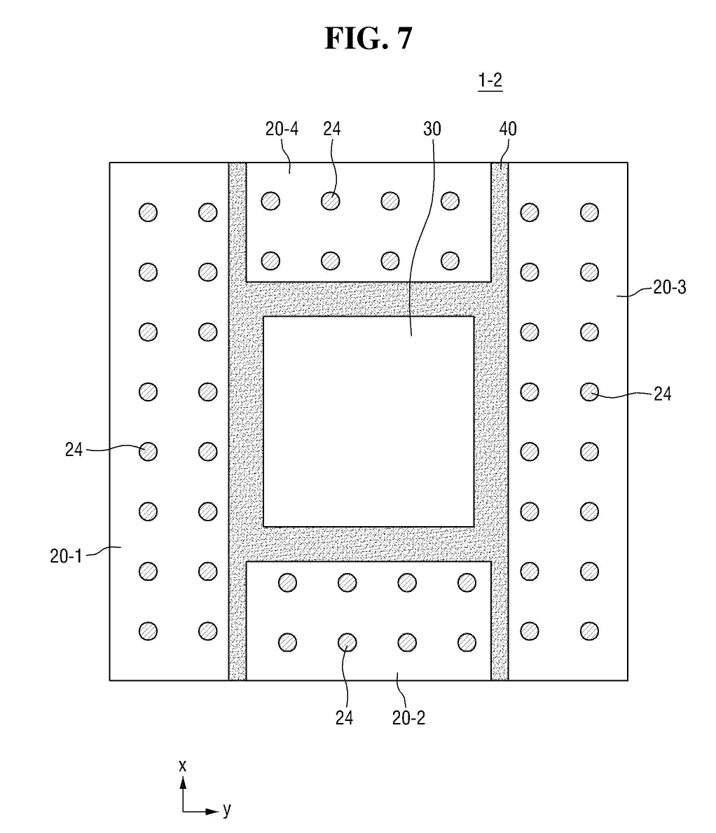

A first semiconductor package in accordance with a second embodiment of the present inventive concepts will now be described with reference to FIG. 7. The following description will be made focusing on differences between this embodiment and the previously described embodiment. FIG. 7 is a somewhat schematic plan view of a first semiconductor package in accordance with a second embodiment of the present inventive concepts.

Referring to FIG. 7, the lengths of the first to fourth segments 20-1, 20-2, 20-3 and 20-4 of the first semiconductor package 1-2 in accordance with the second embodiment may not be equal. For example, the first and third segments 20-1 and 20-3 may have a first length that is the same length, and the second and fourth segments 20-2 and 20-4 may have a second length that is the same length. The first and second lengths may be different from each other.

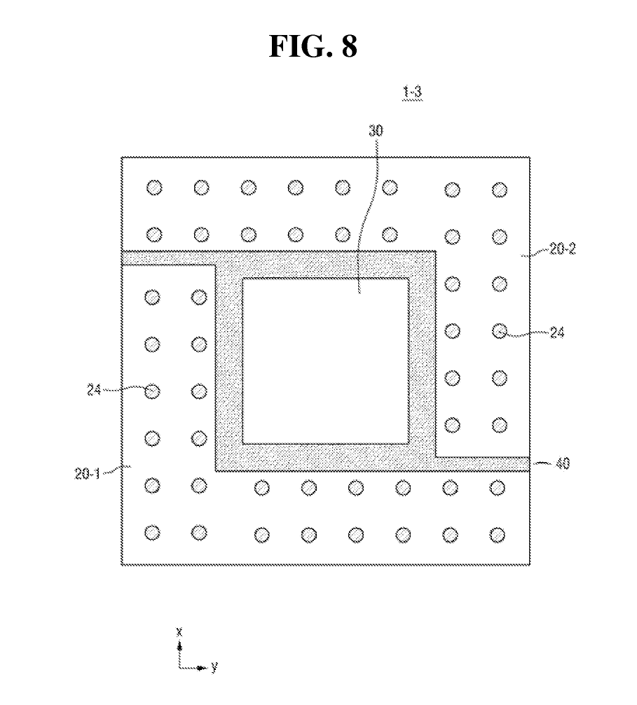

A first semiconductor package in accordance with a third embodiment of the present inventive concepts will now be described with reference to FIG. 8. The following description will be made focusing on differences between this embodiment and the first embodiment. FIG. 8 is a somewhat schematic plan view of the first semiconductor package in accordance with the third embodiment of the present inventive concepts.

Referring to FIG. 8, the segments 20-1 and 20-2 of the first semiconductor package 1-3 in accordance with the third embodiment may not have a straight, stick-like shape. For example, the first and second segments 20-1 and 20-2 may have a shape that is bent. In this embodiment, for instance, the first and second segments 20-1 and 20-2 may have an L-shape.

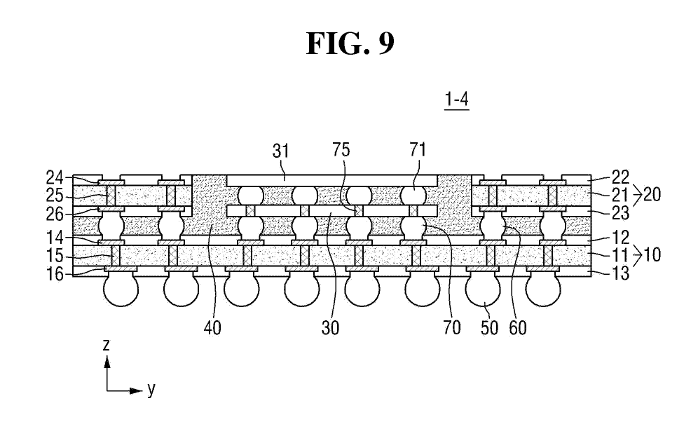

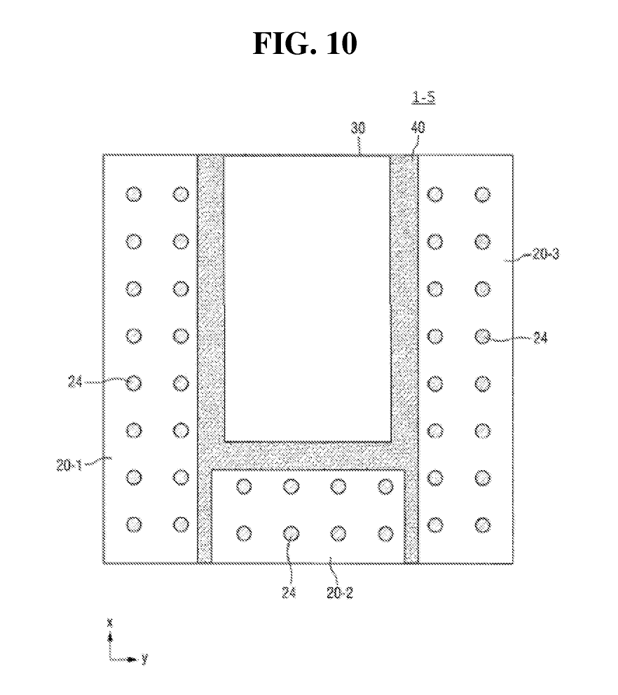

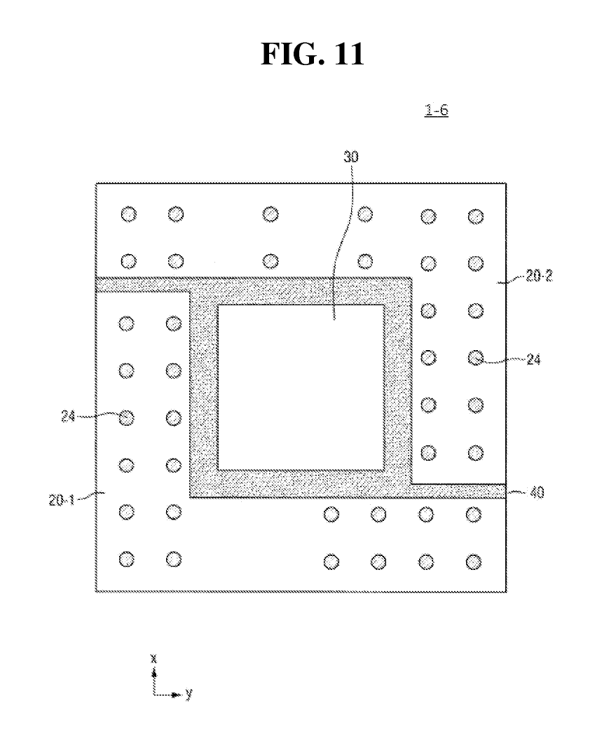

A first semiconductor package in accordance with a fourth embodiment of the present inventive concepts will now be described with reference to FIG. 9. The following description will be made focusing on differences between this embodiment and the first embodiment. FIG. 9 is a somewhat schematic plan view of the first semiconductor package in accordance with the fourth embodiment of the present inventive concepts.

Referring to FIG. 9, a plurality of semiconductor chips may be stacked on the first substrate 10 in the first semiconductor package 1-4 in accordance with the fourth embodiment. More specifically, the first and fourth semiconductor chips 30 and 31 may be stacked on the first substrate 10. The first semiconductor chip 30 may include fourth through electrodes 75 such as through silicon vias. The fourth through electrodes 75 may be formed to pass through the first semiconductor chip 30 from one surface to an opposite surface thereof.

The fourth semiconductor chip 31 may be electrically connected to the first semiconductor chip 30 by fifth external connection terminals 71.

A first semiconductor package in accordance with a fifth embodiment of the present inventive concept will now be described with reference to FIG. 10. The following description will be made focusing on differences between this embodiment and the second embodiment of the present inventive concepts shown in FIG. 7. FIG. 10 is a somewhat schematic plan view of the first semiconductor package in accordance with the fifth embodiment of the present inventive concepts.

Referring to FIG. 10, at least one of the four segments in FIG. 7 may be eliminated when the segment is not necessary to electrically connect the second substrate 110 to the first substrate 10 or where the first semiconductor chip 30 in the first semiconductor package 1-5 is large enough to cover the area occupied by the fourth segment 20-4 in FIG. 7. The segment 20-2 may be a dummy segment which needs not electrically connect the second substrate 110 to the first substrate 10. The segment 20-2 may, however, help reduce the stress between the second substrate 110 to the first substrate 10. The first semiconductor chip 30 may be arranged in the center even without the segment 20-2 according to a size or a shape of the first semiconductor chip 30.

A first semiconductor package in accordance with a sixth embodiment of the present inventive concept will now be described with reference to FIG. 11. The following description will be made focusing on differences between this embodiment and the third embodiment shown in FIG. 8. FIG. 11 is a somewhat schematic plan view of the first semiconductor package in accordance with the sixth embodiment of the present inventive concepts.

Referring to FIG. 11, the pitches and the positions of the third pads 24 of the first and second segments 20-1 and 20-2 may vary according to the external connection terminals of the second package 2 in FIG. 1.

While the present inventive concepts have been particularly shown and described with reference to exemplary embodiments thereof, it will be understood by those of ordinary skill in the art that various changes in form and details may be made therein without departing from the spirit and scope of the present inventive concepts as defined by the following claims. The present embodiments should therefore be considered in all respects as illustrative and not restrictive, with reference being made to the appended claims for the scope of the inventive concepts, rather than solely to the foregoing description.

What is claimed is:

1. A semiconductor package comprising:
a substrate;
a semiconductor chip formed on the substrate; and
an interposer comprising a plurality of segments, wherein the plurality of segments are separated from each other and arranged on the substrate to surround the semiconductor chip.

2. The semiconductor package of claim 1, wherein the segments are arranged separately from the semiconductor chip to surround the semiconductor chip.

3. The semiconductor package of claim 1, wherein the interposer includes first and second segments arranged adjacent to each other, and wherein a sealant is formed to fill up a space between the first and second segments.

4. The semiconductor package of claim 3, wherein the first segment includes a plurality of first pads,
wherein the second segment includes a plurality of second pads, wherein a pitch between the first pads adjacent to each other is equal to a pitch between the second pads adjacent to each other, and
wherein a pitch between the first and second pads adjacent to each other is larger than the pitch between the first pads adjacent to each other.

5. The semiconductor package of claim 3, further comprising a plurality of first external connection terminals which electrically connect the first segment to the substrate, and a plurality of second external connection terminals which electrically connect the second segment to the substrate,
wherein the sealant is formed to fill up a space between the first segment and the substrate, a space between the second segment and the substrate, a space between the first external connection terminals, and a space between the second external connection terminals.

6. The semiconductor package of claim 3, wherein the semiconductor chip includes first and second side surfaces adjacent to each other,
wherein the first segment is located adjacent to the first side surface of the semiconductor chip, and
wherein the second segment is located adjacent to the second side surface of the semiconductor chip.

7. The semiconductor package of claim 1, wherein each of the segments is separated from the substrate by the same distance.

8. The semiconductor package of claim 1, wherein all of the segments have the same length.

9. The semiconductor package of claim 1, wherein the segments are arranged in a rectangular shape to surround the semiconductor chip.

10. The semiconductor package of claim 1, wherein the semiconductor chip is flip-chip bonded to the substrate, and
wherein a distance from the substrate to an upper surface of the semiconductor chip is equal to a distance from the substrate to an upper surface of the interposer.

11. A semiconductor package comprising:
a substrate;
a semiconductor chip formed on the substrate and including first and second side surfaces adjacent to each other;
an interposer including a first segment adjacent to the first side surface of the semiconductor chip and a second segment adjacent to the second side surface of the semiconductor chip, the first and second segments being formed separately from each other on the substrate; and
a sealant formed to fill up a space between the first and second segments.

12. The semiconductor package of claim 11, wherein the semiconductor chip further includes a third side surface opposite to the first side surface, and a fourth side surface opposite to the second side surface,
wherein the interposer further includes a third segment adjacent to the third side surface of the semiconductor chip and a fourth segment adjacent to the fourth side surface of the semiconductor chip, wherein the third and fourth segments are formed separately from each other on the substrate, and
wherein the semiconductor chip is surrounded by the first to fourth segments.

13. The semiconductor package of claim 12, wherein the first to fourth segments each have the same length.

14. The semiconductor package of claim 11, wherein the first segment includes a plurality of first pads,
wherein the second segment includes a plurality of second pads,
wherein a pitch between the first pads adjacent to each other is equal to a pitch between the second pads adjacent to each other, and
wherein a pitch between the first and second pads adjacent to each other is larger than the pitch between the first pads adjacent to each other.

15. The semiconductor package of claim 11, wherein a distance between the first segment and the substrate is equal to a distance between the second segment and the substrate.

16. A semiconductor package comprising:
a first substrate;
a first semiconductor chip formed on the first substrate;
an interposer including a plurality of segments which are separated from each other and arranged on a plane along with the first semiconductor chip;
a second substrate formed on the interposer and the first semiconductor chip; and
a second semiconductor chip formed on the second substrate.

17. The semiconductor package of claim 16, wherein the second semiconductor chip is bonded to the second substrate by wire.

18. The semiconductor package of claim 16, wherein the second semiconductor chip is flip-chip bonded to the second substrate.

19. The semiconductor package of claim 16, wherein the second semiconductor chip includes a plurality of second pads and the first substrate includes a plurality of first pads which are electrically connected to the second pads through the interposer.

20. The semiconductor package of claim 16, further comprising a plurality of first external connection terminals which electrically connect a first segment of the interposer to the first substrate.
